(19) United States
(12) Patent Application Publication
(10) Pub. No.: US 2017/0207267 A1
(43) Pub. Date: Jul. 20, 2017

(54) IMAGE SENSOR AND METHOD OF MANUFACTURING THE SAME

(71) Applicant: SAMSUNG ELECTRONICS CO., LTD., Suwon-si (KR)

(72) Inventors: DONGHYUK PARK, YONGIN-SI (KR); SEUNGWON CHA, SEOUL (KR); CHEOLJU KANG, SEOUL (KR); YITAE KIM, HWASEONG-SI (KR); JONGEUN PARK, SEONGNAM-SI (KR); JUNGCHAK AHN, YONGIN-SI (KR); YUJUNG CHOI, YONGIN-SI (KR)

(21) Appl. No.: 15/410,859

(22) Filed: Jan. 20, 2017

(30) Foreign Application Priority Data
Jan. 20, 2016 (KR) 10-2016-0007215

(51) Int. Cl. H01L 27/146

(52) U.S. Cl. CPC H01L 27/14623; H01L 27/1463; H01L 27/14636; H01L 27/14621; H01L 27/14627; H01L 27/14645; H01L 27/14689; H01L 27/14685; H04N 5/378

(57) ABSTRACT

An image sensor is provided. The image sensor includes a light shielding layer having a grid structure corresponding to a device isolation layer defining a plurality of pixel regions. The light shielding layer includes holes exposing the plurality of pixel regions, respectively. The light shielding layer is connected to a charge pump applying a negative voltage.

### CROSS-REFERENCE TO RELATED APPLICATION

This U.S. non-provisional patent application claims priority under 35 U.S.C. §119 to Korean Patent Application No. 10-2016-0007215, filed on Jan. 20, 2016, in the Korean Intellectual Property Office, the disclosure of which is incorporated by reference herein in its entirety.

### TECHNICAL FIELD

Exemplary embodiments of the inventive concept relate to an image sensor and a method of manufacturing the same and, more particularly, to a complementary metal-oxide-semiconductor (CMOS) image sensor (CIS) and a method of manufacturing the same.

### DISCUSSION OF RELATED ART

Image sensors are semiconductor devices converting an optical image into electrical signals. Image sensors may be categorized as either charge coupled device (CCD) image sensors or complementary metal-oxide-semiconductor (CMOS) image sensors. The CMOS image sensor (CIS) may include a plurality of two-dimensionally arranged pixels. Each of the pixels may include a photodiode (PD). The photodiode may convert incident light into an electrical signal.

As semiconductor devices become highly integrated, image sensors are also highly integrated. Accordingly, sizes of pixels may be reduced and areas of photodiodes may also be reduced. Since the areas of the photodiodes are reduced, photosensitivity of the photodiodes may be reduced by small factors or external environment.

### SUMMARY

Exemplary embodiments of the inventive concept may provide an image sensor with excellent photosensitivity, and a method of manufacturing the same.

In an aspect of the inventive concept, an image sensor may include a device isolation layer disposed in a substrate to define a plurality of pixel regions, an interconnection structure disposed on a first surface of the substrate, the interconnection structure including an interconnection electrically connected to a transistor, a light shielding layer disposed on a second surface, opposite to the first surface, of the substrate, and a charge pump applying a negative voltage to the light shielding layer. The light shielding layer may have a grid structure having holes exposing the plurality of pixel regions, and the grid structure may vertically overlap with the device isolation layer.

In another aspect of the inventive concept, a method of manufacturing an image sensor may include forming a device isolation layer in a substrate to define pixel regions, forming a photoelectric conversion layer and a floating diffusion region in each of the pixel regions, forming an interconnection structure on a first surface of the substrate, forming a light shielding layer on a second surface of the substrate, performing a curing process on the second surface of the substrate, and applying a negative voltage to the light shielding layer to remove positive charges remaining between the second surface of the substrate and the light shielding layer.

In still another aspect of the inventive concept, an image sensor may include a semiconductor substrate having a first surface and a second surface opposite to the first surface, and having a pixel region which includes a photoelectric conversion layer formed in the semiconductor substrate to generate photocharges, a well dopant layer disposed between the photoelectric conversion layer and the first surface of the semiconductor substrate in the pixel region, a transfer gate disposed on the first surface of the semiconductor substrate for transferring the photocharges accumulated in the photoelectric conversion layer into a floating diffusion region, the floating diffusion region disposed in the well dopant layer at a side of the transfer gate, a light shielding layer disposed on the second surface of the semiconductor substrate and having a hole exposing the pixel region, and a charge pump connected to the light shielding layer for applying a negative voltage to remove positive charges.

### BRIEF DESCRIPTION OF THE DRAWINGS

The inventive concept will become more apparent in view of the detailed description of the exemplary embodiments and the accompanying drawings, in which:

FIG. 1 is a schematic block diagram illustrating an image sensor according to an exemplary embodiment of the inventive concept;

FIG. 2 is a circuit diagram illustrating an active pixel sensor array of an image sensor according to an exemplary embodiment of the inventive concept;

FIG. 3 is a plan view illustrating an image sensor according to an exemplary embodiment of the inventive concept;

FIGS. 4 and 5 are cross-sectional views taken along a line I-I′ of FIG. 3;

FIGS. 6 to 10 are cross-sectional views illustrating a method of manufacturing an image sensor according to an exemplary embodiment of the inventive concept; and

FIG. 11 is a graph illustrating a difference between dark levels of a pixel region and an optical black region versus a value of a negative voltage applied to a light shielding layer of an image sensor according to an exemplary embodiment of the inventive concept.

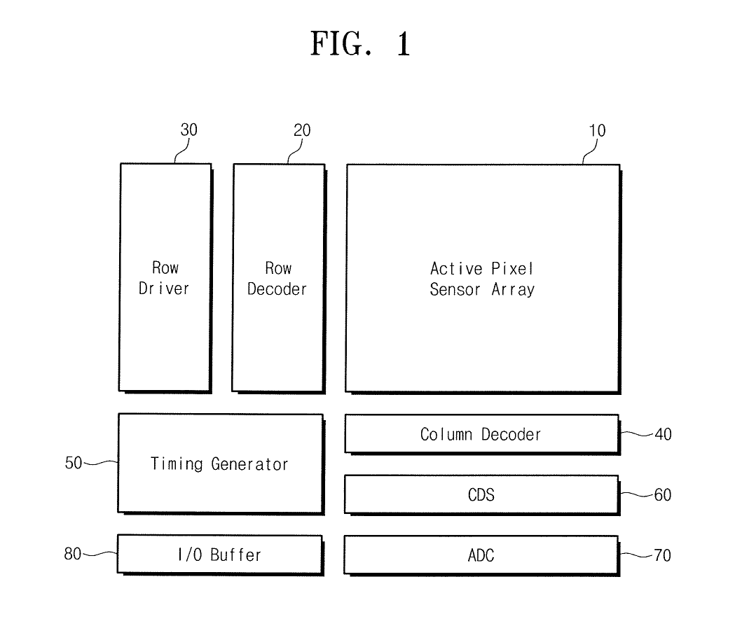

Since the drawings in FIGS. 1-11 are intended for illustrative purposes, the elements in the drawings are not necessarily drawn to scale. For example, some of the elements may be enlarged or exaggerated for clarity purpose.

### DETAILED DESCRIPTION OF THE EMBODIMENTS

The present invention will be described more fully hereinafter with reference to the accompanying drawings, in which exemplary embodiments of the inventive concept are shown.

FIG. 1 is a schematic block diagram illustrating an image sensor according to an exemplary embodiment of the inventive concept.

Referring to FIG. 1, an image sensor may include an active pixel sensor array 10, a row decoder 20, a row driver 30, a column decoder 40, a timing generator 50, a correlated double sampler (CDS) 60, an analog-to-digital converter (ADC) 70, and an input/output (I/O) buffer 80.

The active pixel sensor array 10 may include a plurality of unit pixels two-dimensionally arranged, and may convert optical signals into electrical signals. The active pixel sensor array 10 may be driven by a plurality of driving signals (e.g., a pixel selection signal, a reset signal, and a charge transfer signal) provided from the row driver 30. The generated electrical signals from the active pixel sensor array 10 may be provided to the correlated double sampler 60.

The row driver 30 may provide the plurality of driving signals for driving the plurality of unit pixels to the active pixel sensor array 10 in response to signals decoded in the row decoder 20. When the unit pixels are arranged in a matrix form, the driving signals may be provided to each row of the matrix.

The timing generator 50 may provide timing signals and control signals to the row decoder 20 and the column decoder 40. The row decoder 20 may be used to address the pixel rows, and the column decoder 40 may be to arrange the digital counters to export their output signals in series.

The correlated double sampler 60 may receive an electrical signal generated from the active pixel sensor array 10 and may hold and sample the received electrical signal. The correlated double sampler 60 may sample a specific noise level and a signal level of the electrical signal to output a difference level corresponding to a difference between the noise level and the signal level. Thus, undesired offset or noise may be removed from the electrical signal.

The analog-to-digital converter 70 may convert an analog signal, which corresponds to the difference level outputted from the correlated double sampler 60, into a digital signal. The analog-to-digital converter 70 may output the digital signal. Normally, the readout circuitry includes the row decoder 20 and the column decoder 40 for addressing the pixels, and the correlated double sampler 60 and the analog-to-digital converter 70 for signal processing.

The I/O buffer 80 may latch the digital signals and may sequentially output the latched digital signals to an image signal processing part in response to signals decoded in the column decoder 40.

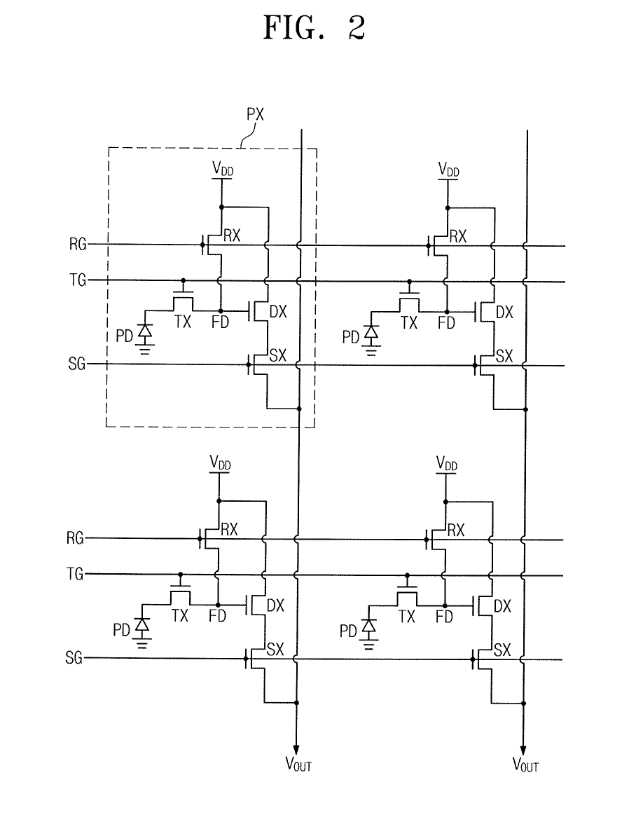

FIG. 2 is a circuit diagram illustrating an active pixel sensor array of an image sensor according to an exemplary embodiment of the inventive concept.

Referring to FIGS. 1 and 2, the active pixel sensor array 10 may include a plurality of unit pixels PX. The plurality of unit pixels PX may be arranged in a matrix form. In the present embodiment, the unit pixel PX may include a transfer transistor TX and logic transistors RX, SX, and DX. Here, the logic transistors may include a reset transistor RX, a selection transistor SX, and a drive transistor (or a source follower transistor) DX. The transfer transistor TX may include a transfer gate TG, a photoelectric conversion element PD, and a floating diffusion region FD.

The photoelectric conversion element PD may generate photocharges in proportion to the amount of incident light and may accumulate the generated photocharges. In an exemplary embodiment of the inventive concept, the photoelectric conversion element PD may be configured to be responsive to visible light for generating photocharges. The photoelectric conversion element PD may include, for example, a photodiode, a photo transistor, a photo gate, a pinned photodiode (PPD), or any combination thereof. The transfer gate TG may receive a charge transfer signal and may transfer the charges accumulated in the photoelectric conversion element PD into the floating diffusion region FD. The floating diffusion region FD may receive the charges generated in the photoelectric conversion element PD and may cumulatively store the received charges. The gate of the drive transistor DX may be connected to the floating diffusion region FD. The drive transistor DX may be connected between a power voltage V_{DD} and the select transistor SX, and may be controlled according to the amount of the photocharges accumulated in the floating diffusion region FD.

The reset transistor RX may periodically reset the charges accumulated in the floating diffusion region FD. A drain electrode of the reset transistor RX may be connected to the floating diffusion region FD, and a source electrode of the reset transistor RX may be connected to the power voltage V_{DD}. When the reset transistor RX is turned-on, the power voltage V_{DD} connected to the source electrode of the reset transistor RX may be transmitted to the floating diffusion region FD. Thus, when the reset transistor RX is turned-on, the charges accumulated in the floating diffusion region FD may be discharged to reset the floating diffusion region FD.

The drive transistor DX and a constant current source may constitute a source follower buffer amplifier. The constant current source may be disposed outside the unit pixel PX. The drive transistor DX may amplify a potential variation of the floating diffusion region FD and may provide the amplified potential variation to an output line V_{OUT}.

The unit pixel PX may be selected through the selection transistor SX. In an exemplary embodiment of the inventive concept, the unit pixels PX of a row to be sensed may be selected simultaneously through the selection transistors SX thereof. When the selection transistor SX is turned-on, the power voltage V_{DD} may be transmitted to a source electrode of the drive transistor DX.

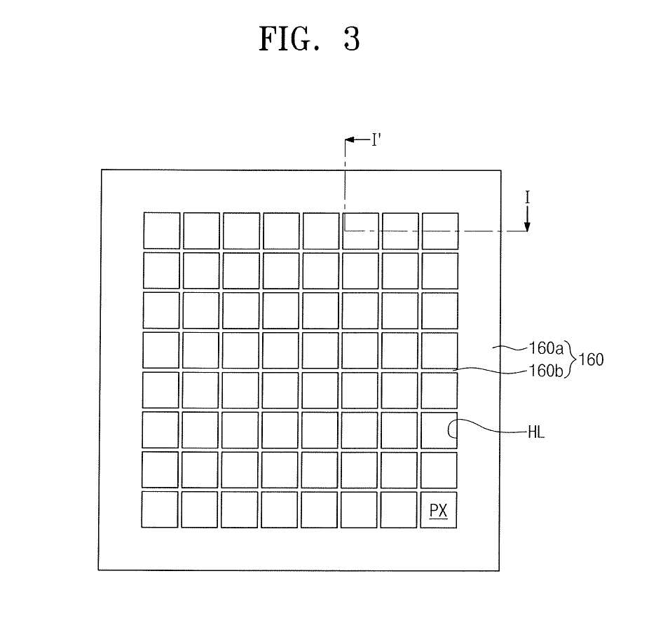

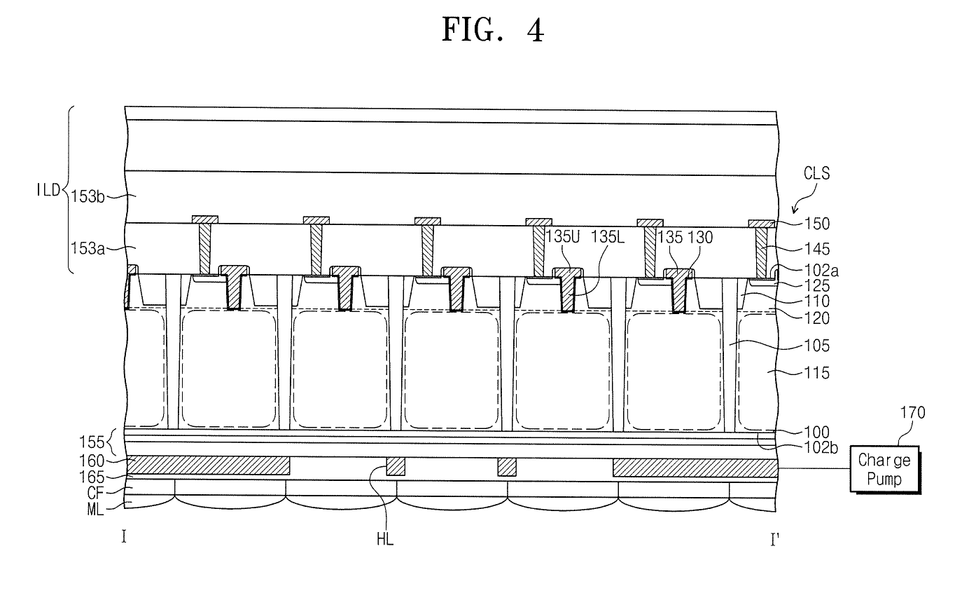

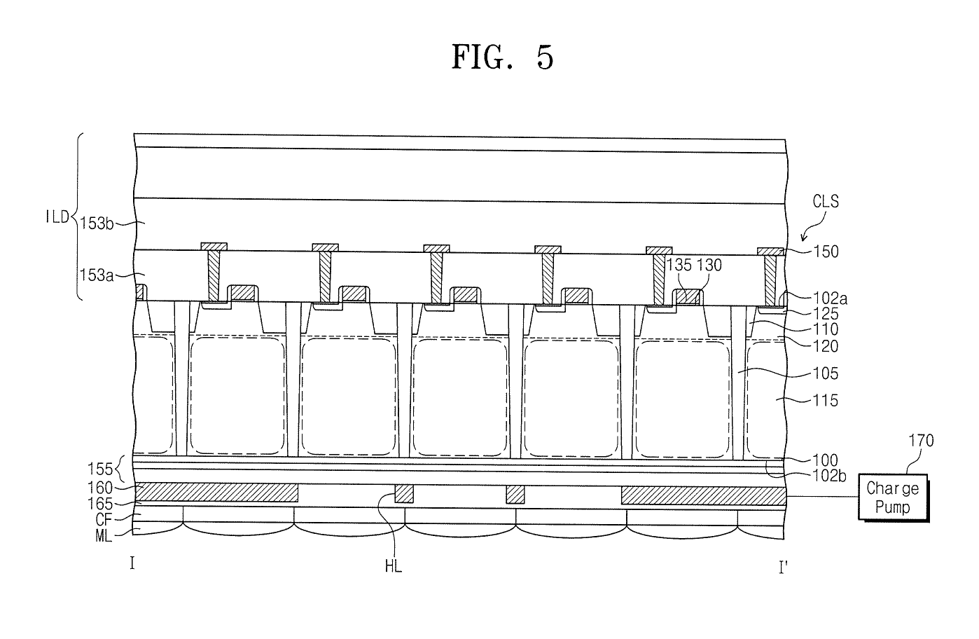

FIG. 3 is a plan view illustrating an image sensor according to an exemplary embodiment of the inventive concept. FIGS. 4 and 5 are cross-sectional views taken along line I-I′ of FIG. 3.

Referring to FIGS. 3, 4, and 5, a substrate 100 may include a plurality of pixel regions PX. The plurality of pixel regions PX may be arranged along an x-axis direction and a y-axis direction. The substrate 100 may include an optical black region. The optical black region may be disposed at an edge of the substrate 100 to surround the plurality of pixel regions PX. Each of the plurality of pixel regions PX may receive incident light and may convert the received light into electrical signals. The optical black region may shield light and may provide a reference of a black signal to the (active) pixel region PX for processing an image signal. Since light has been shield in the optical black region, the black signal may not be the photo-electrically converted electrical signal, and may be thermally generated electrical signal. Variation of the black signal may occur when charges are trapped in the optical black region.

The substrate 100 may be a semiconductor substrate including silicon, germanium, or silicon-germanium (SiGe), or may be a silicon-on-insulator (SOI) substrate, a germanium-on-insulator (GOI) substrate, or a substrate including a semiconductor epitaxial layer. The substrate 100 may have a first surface 102a and a second surface 102b which are opposite to each other.

Hereinafter, the first surface 102a of the substrate 100 will be first described. An interconnection structure CLS may be disposed on the first surface 102a of the substrate 100. The interconnection structure CLS may include at least one interlayer insulating layer ILD, contact plugs 145, and interconnections 150. The interconnections 150 may be electrically connected to transfer transistors and logic transistors (e.g., reset transistor, selection transistor, and drive transistor) through the contact plugs 145.

Each of the plurality of pixel regions PX may include a photoelectric conversion layer 115 and a well dopant layer 120 which are formed in the substrate 100. The photoelectric conversion layer 115 may generate photocharges in proportion to an intensity of incident light. The photoelectric conversion layer 115 may be formed by implanting dopants into the substrate 100. A conductivity type of the photoelectric conversion layer 115 may be opposite to that of the substrate 100. The photoelectric conversion layer 115 may include a first region adjacent to the first surface 102a of the substrate 100 and a second region adjacent to the second surface 102b of the substrate 100. In an exemplary embodiment of the inventive concept, a dopant concentration of the first region of the photoelectric conversion layer 115 may be different from that of the second region of the photoelectric conversion layer 115, and thus the photoelectric conversion layer 115 may have a potential gradient between the first surface 102a and the second surface 102b of the substrate 100. For example, the photoelectric conversion layer 115 may include a plurality of stacked dopant regions. The substrate 100 may also include the well dopant layer 120 adjacent to the first surface 102a of the substrate 100, and may be interposed between the photoelectric conversion layer 115 and the first surface 102a of the substrate. The well dopant layer 120 may be doped with dopants of which a conductivity type is opposite to that of the photoelectric conversion layer 115. In an exemplary embodiment of the inventive concept, the photoelectric conversion layer 115 may be doped with N-type dopants, and the well dopant layer 120 may be doped with P-type dopants.

A first device isolation layer 105 may be provided in the substrate 100 to define the pixel regions PX. The first device isolation layer 105 may vertically extend from the first surface 102a to the second surface 102b of the substrate 100, and may surround the photoelectric conversion layer 115. The first device isolation layer 105 may be formed of an insulating material of which a refractive index is lower than that of the substrate 100. For example, the first device isolation layer 105 may include, for example, silicon oxide, silicon nitride, undoped poly-silicon, air, or any combination thereof. The first device isolation layer 105 may refract light obliquely incident on the photoelectric conversion layer 115. The first device isolation layer 105 may prevent photocharges generated in a pixel region PX by the incident light from moving into neighboring pixel regions PX. A second device isolation layer 110 may be provided in the substrate 100 of each pixel region PX to define at least one active pattern. A top surface of the first device isolation layer 105 may be coplanar with a top surface of the second device isolation layer 110. A distance between the first surface 102a of the substrate 100 and a bottom surface of the second device isolation layer 110 may be smaller than a distance between the first surface 102a of the substrate 100 and a bottom surface of the first device isolation layer 105.

A transfer gate 135 and a floating diffusion region 125 may be disposed in each of the plurality of pixel regions PX. The transfer gate 135 may transfer photocharges accumulated in the photoelectric conversion layer 115 into the floating diffusion region 125. The transfer of the photocharges may correspond to the receiving of a charge transfer signal by the transfer gate 135. Referring to FIG. 4, the transfer gate 135 may include a lower portion 135L inserted in the well dopant layer 120 and an upper portion 135U connected to the lower portion 135L. The upper portion 135U may protrude from the first surface 102a of the substrate 100. The lower portion 135L of the transfer gate 135 may penetrate a portion of the well dopant layer 120. A gate insulating layer 130 may be disposed between the transfer gate 135 and the substrate 100. In an exemplary embodiment of the inventive concept, a trench may be formed in the well dopant layer 120, and the gate insulating layer 130 and the transfer gate 135 may be sequentially stacked on an inner surface of the trench. Alternatively, referring to FIG. 5, the transfer gate 135 may be disposed on the well dopant layer 120. A gate insulating layer 130 may be disposed between the transfer gate 135 and the substrate 100.

The floating diffusion region 125 may be formed in the well dopant layer 120 at a side of the transfer gate 135 by using an ion implantation process. The floating diffusion region 125 may be doped with dopants of which a conductivity type is opposite to that of the well dopant layer 120. For example, the well dopant layer 120 may be a P-type dopant region, and the floating diffusion region 125 may be an N-type dopant region. The transfer transistor may include the transfer gate 135, the photoelectric conversion layer 115, and the floating diffusion region 125.

Even though not shown in detail in the drawings, a reset gate, a selection gate, and a source follower gate may be disposed on the substrate 100 of each of the plurality of pixel regions PX. Each of the reset, selection and source follower gates may be disposed on the well dopant layer 120 with an gate insulating layer interposed therebetween.

A plurality of interlayer insulating layers ILD may be disposed on the first surface 102a of the substrate 100. For example, a first interlayer insulating layer 153a may be disposed on the first surface 102a of the substrate 100. The first interlayer insulating layer 153a may cover the transfer gate 135, the reset gate, the selection gate, and the source follower gate. Contact plugs 145 may be disposed in the first interlayer insulating layer 153a. The contact plugs 145 may be electrically connected to the interconnections 150 disposed on the first interlayer insulating layer 153a, and may also be electrically connected to the floating diffusion region 125 formed in the well dopant layer 120. A second interlayer insulating layer 153b may be provided to cover the interconnections 150. Even though not shown in detail in the drawings, contact plugs may be disposed in each of the plurality of interlayer insulating layers ILD, and interconnections may be disposed directly on each of the plurality of interlayer insulating layers ILD. Each of the contact plug 145 and the interconnection 150 may include, for example, at least one of copper (Cu), aluminum (Al), tungsten (W), titanium (Ti), molybdenum (Mo), tantalum (Ta), titanium nitride (TiN), tantalum nitride (TaN), zirconium nitride (ZrN), tungsten nitride (WN), and any combination thereof.

Hereinafter, the second surface 102b of the substrate 100 will be described. A light shielding layer 160, a color filter layer CF, and micro lenses ML may be disposed on the second surface 102b of the substrate 100.

The light shielding layer 160 may cover the second surface 102b of the substrate 100, and may have a plurality of holes HL. The plurality of holes HL may correspond to the plurality of pixel regions PX, respectively, and thus the plurality of pixel regions PX may receive light through the plurality of holes HL. For example, the light shielding layer 160 may have a grid structure when viewed from a plan view. The grid structure may correspond to a planar structure of the first device isolation layer 105. In other words, the grid structure may vertically overlap with the first device isolation layer 105. In an exemplary embodiment of the inventive concept, as illustrated in FIG. 3, the light shielding layer 160 may include a first portion 160a surrounding the plurality of pixel regions PX and second portions 160b intersecting an inner space of the first portion 160a in a longitudinal direction and a transverse direction. The inner space of the first portion 160a may mean a space surrounded by the first portion 160a when viewed from a plan view. The first portions 160a and the second portions 160b may be in one body. The light shielding layer 160 may include, for example, at least one of tungsten (W), copper (Cu), hafnium (I-If), zirconium (Zr), titanium (Ti), tantalum (Ta), aluminum (Al), ruthenium (Ru), palladium (Pd), platinum (Pt), cobalt (Co), and nickel (Ni).

A connection line may be connected to the light shielding layer 160, and may be connected to a charge pump 170 disposed in the image sensor. Thus, a negative voltage may be applied from the charge pump 170 to the light shielding layer 160 through the connection line. In an exemplary embodiment of the inventive concept, the negative voltage may be a constant voltage. The light shielding layer 160 may be disconnected from a ground source.

The charge pump 170 may be electrically connected to all elements of the image sensor, which need a negative voltage. For example, the charge pump 170 may apply a negative voltage to the transfer gate 135. For example, the transfer transistor including the transfer gate 135 may be turned-on when the transfer gate 135 receives a positive voltage from a positive charge pump. On the other hand, the transfer transistor may be turned-off when the transfer gate 135 receives the negative voltage from the charge pump 170.

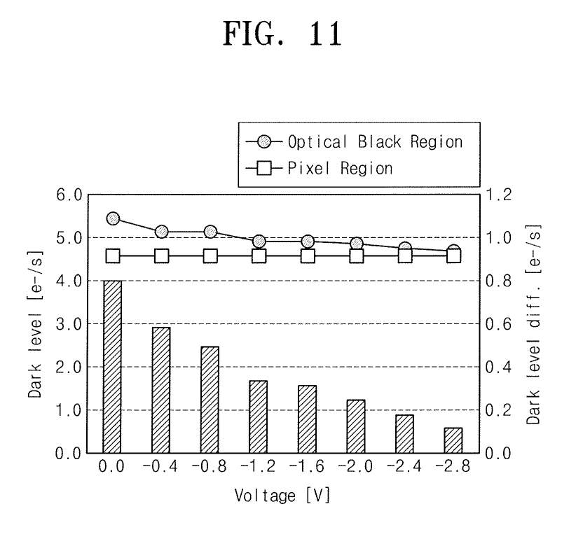

The light shielding layer 160 may shield light, and may offset or remove positive charges by applying a negative voltage from the charge pump 170 to the light shielding layer 160. In an exemplary embodiment of the inventive concept, positive holes (h+) may be generated at the second surface 102b of the substrate 100 during a process of depositing a metal (e.g., tungsten) and a back-end process (e.g., an etching or polishing process) performed on the second surface 102b of the substrate 100. In general, the positive holes (h+) may be cured using ultraviolet (UV) or plasma. However, some of the positive holes (h+) may remain between the light shielding layer 160 and the substrate 100 after the UV or plasma curing process. According to an exemplary embodiment of the inventive concept, the positive holes (h+) remaining between the light shielding layer 160 and the second surface 102b of the substrate 100 may be removed by the negative voltage applied to the light shielding layer 160. As a result, it is possible to reduce or minimize a difference value between a black level of the optical black region and a black level of each of the plurality of pixel regions PX. This will be described later in more detail with reference to FIG. 11.

A first planarization layer 155 may be disposed between the second surface 102b of the substrate 100 and the light shielding layer 160. The first planarization layer 155 may include a plurality of stacked layers. Since the light shielding layer 160 includes the plurality of holes HL, a second planarization layer 165 may be disposed between the light shielding layer 160 and the color filter layer CF to fill the holes HL. The second planarization layer 165 may also include a plurality of stacked layers. Each of the first and second planarization layers 155 and 165 may include a transparent insulating material, e.g., silicon oxide.

The color filter layer CF may include a plurality of color filters. Each of the plurality of color filters and each of the micro lenses ML may be formed to correspond to each of the plurality of pixel regions PX. The color filter layer CF may include red, green and blue color filters.

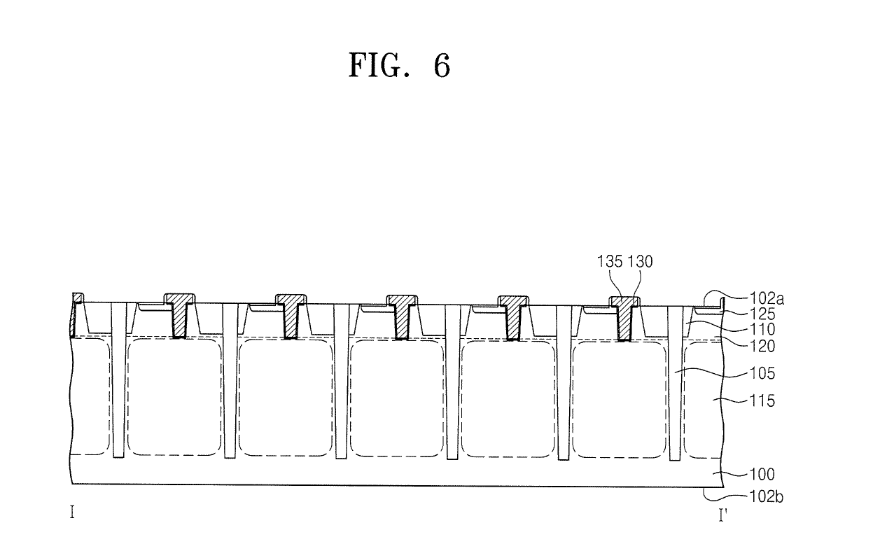

FIGS. 6 to 10 are cross-sectional views illustrating a method of manufacturing an image sensor according to an exemplary embodiment of the inventive concept. Hereinafter, the terms first, second etc. do not mean a formation order.

Referring to FIG. 6, a second device isolation layer 110, a first device isolation layer 105, photoelectric conversion layers 115, well dopant layers 120, transfer gates 135, and floating diffusion regions 125 may be formed at a substrate 100.

In an exemplary embodiment of the inventive concept, a first trench having a first depth from a first surface 102a of the substrate 100 may be formed in the substrate 100, and the second device isolation layer 110 may be formed by filling the first trench with an insulating material. The second device isolation layer 110 may define at least one active pattern in each of the plurality of pixel regions PX. A second trench having a second depth from the first surface 102a may be formed in the substrate 100, and the first device isolation layer 105 may be formed by filling the second trench with an insulating material. The second depth may be greater than the first depth. The forming of the first and second trenches may be achieved by lithography and etching. The first device isolation layer 105 may define the plurality of pixel regions PX. The first device isolation layer 105 may have a grid structure when viewed from a plan view. For example, the formation of the first device isolation layer 105 may be achieved by etching through the first surface of the substrate to form the second trench having a grid structure (e.g., using a photoresist pattern having a grid structure opening as an etch mask) defining the pixel regions in the substrate, and then filling the second trench with an insulating material. The first device isolation layer 105 may vertically overlap with a portion of the second device isolation layer 110.

Dopant ions of a first conductivity type may be implanted into the substrate 100 through the first surface 102a to form the photoelectric conversion layers 115. The first conductivity type may be opposite to a conductivity type of dopants included in the substrate 100. Dopant ions of a second conductivity type opposite to the first conductivity type may be implanted into the substrate 100 to form the well dopant layers 120 on the photoelectric conversion layers 115. The first conductivity type may be N-type, and the second conductivity type may be P-type. The first surface 102a of the substrate 100 may be selectively etched to form third trenches in the well dopant layers 120, and a gate insulating layer and a gate conductive layer may be sequentially formed on inner surfaces of the third trenches and the first surface 102a. The gate conductive layer may be patterned to form the transfer gates 135.

Dopant ions of the first conductivity type may be implanted into the well dopant layers 120 using the transfer gates 135 as ion implantation masks, thereby forming the floating diffusion regions 125.

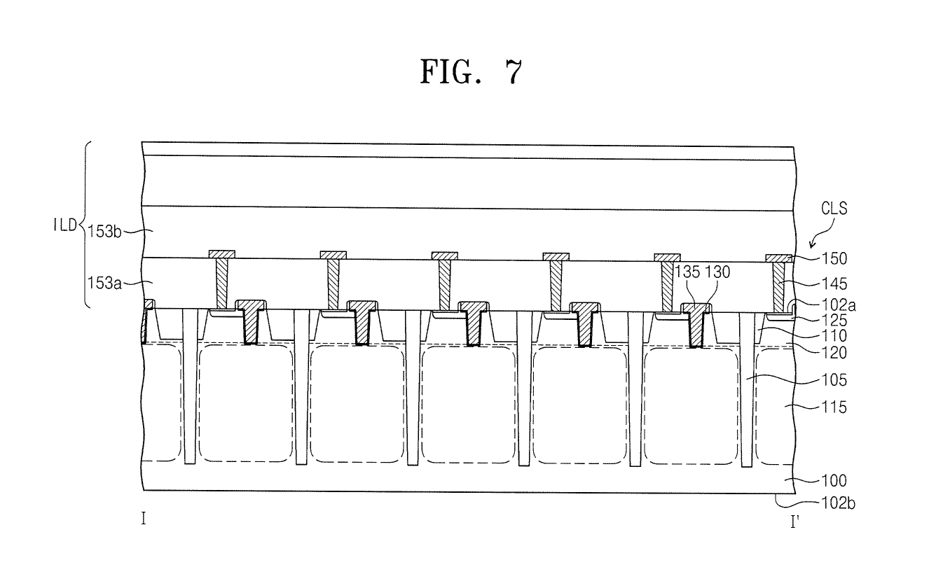

Referring to FIG. 7, an interconnection structure CLS may be formed on the first surface 102a of the substrate 100. The interconnection structure CLS may include a plurality of interlayer insulating layers ILD, contact plugs 145, and interconnections 150.

A first interlayer insulating layer 153a covering the transfer gates 135 may be formed on the first surface 102a of the substrate 100, and contact plugs 145 may be formed to penetrate the first interlayer insulating layer 153a. The contact plugs 145 may be electrically connected to the floating diffusion regions 125. The interconnections 150 may be formed on the first interlayer insulating layer 153a, and may be electrically connected to the floating diffusion regions 125 through the contact plugs 145. A second interlayer insulating layer 153b may then be formed on the first interlayer insulating layer 153a and the interconnections 150. Processes similar to these processes may be repeatedly performed to complete the interconnection structure CLS.

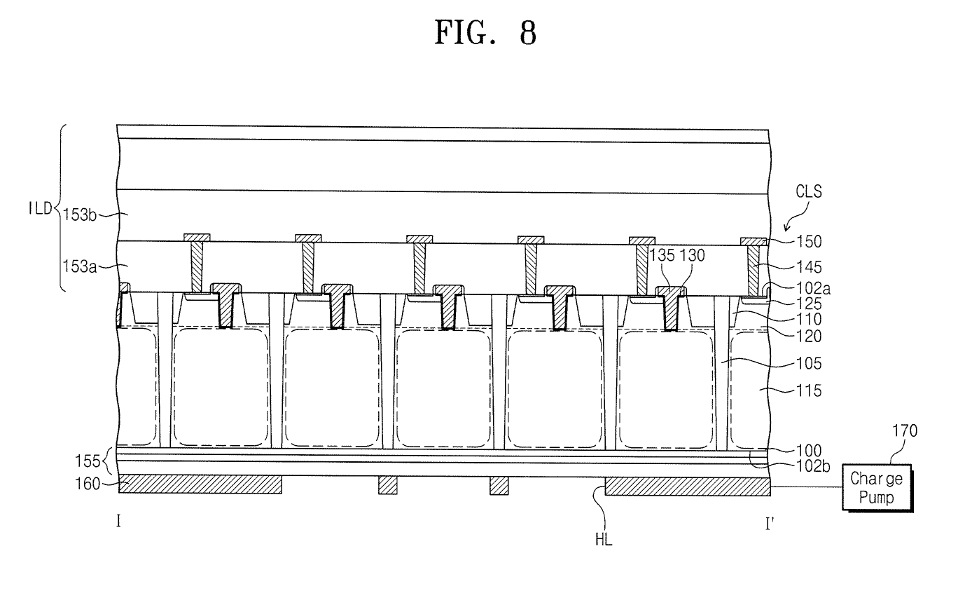

Referring to FIG. 8, a second surface 102b of the substrate 100 may be polished or etched to expose a bottom surface of the first device isolation layer 105, and then a first planarization layer 155 may be formed on the second surface 102b of the substrate 100. The first planarization layer 155 may include a plurality of layers stacked on the second surface 102b of the substrate 100. The first planarization layer 155 may include a transparent insulating material. For example, the first planarization layer 155 may include silicon oxide.

A light shielding layer 160 may be formed on the first planarization layer 155. In an exemplary embodiment of the inventive concept, a metal layer may be formed on the first planarization layer 155, and the metal layer may be patterned to form the light shielding layer 160 having holes HL exposing the pixel regions PX, respectively. The metal layer may be formed on the first planarization layer 155 with various deposition processes which include, but are not limited to: physical vapor deposition (PVD), chemical vapor deposition (CVD), atomic layer deposition (ALD), and electrochemical deposition. Patterning the metal layer may be achieved by lithography and etching. The light shielding layer 160 may have a grid structure corresponding to the first device isolation layer 105. The light shielding layer 160 may include, for example, at least one of tungsten (W), copper (Cu), hafnium (Hf), zirconium (Zr), titanium (Ti), tantalum (Ta), aluminum (Al), ruthenium (Ru), palladium (Pd), platinum (Pt), cobalt (Co), and nickel (Ni).

The light shielding layer 160 may be electrically connected to a charge pump 170 disposed in a logic or controller region of an image sensor. In other words, a new charge pump is not needed to apply the negative voltage, but the light shielding layer 160 may be connected to an internal line, which is supplied with a negative voltage in the image sensor, through a connection line. Thus, the light shielding layer 160 may be supplied with the negative voltage. In addition, the light shielding layer 160 may be disconnected from a connection line connected to a ground source.

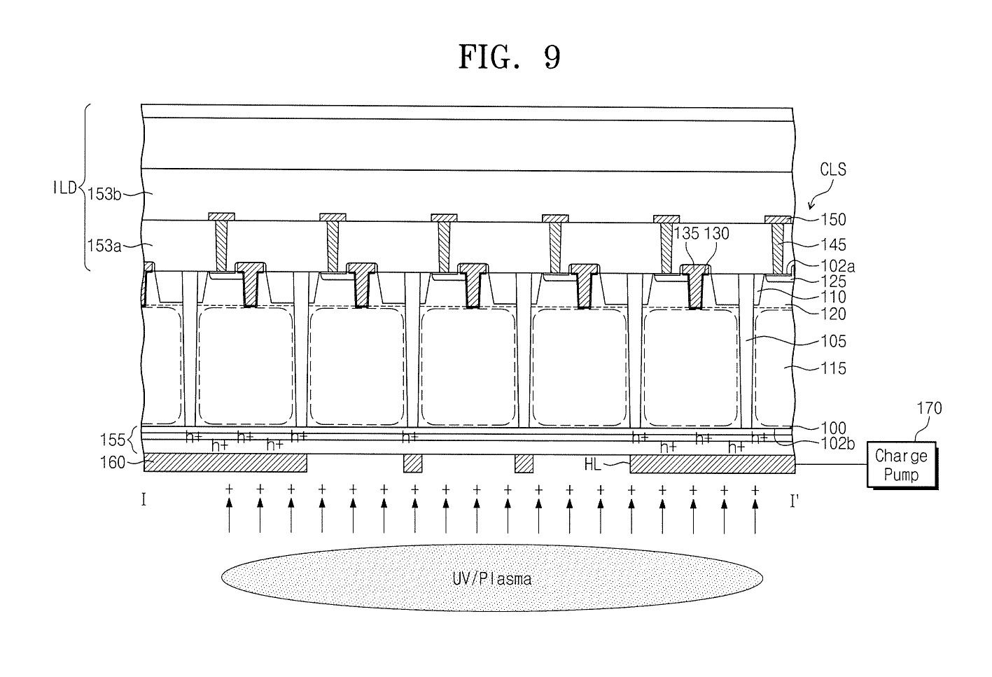

Referring to FIG. 9, a UV or plasma curing process may be performed on the second surface 102b of the substrate 100. The curing process may be performed using plasma having positive charges, and thus the positive charges may remain between the light shielding layer 160 and the second surface 102b of the substrate 100.

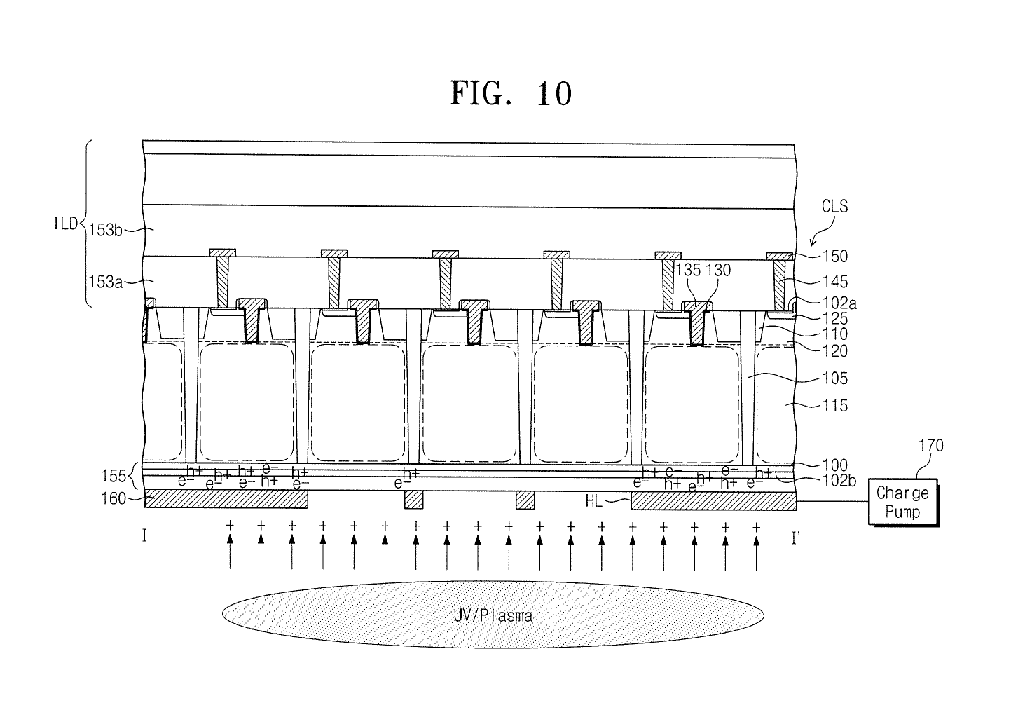

Referring to FIG. 10, the negative voltage may be applied from the charge pump 170 to the light shielding layer 160 to offset or remove the remaining positive charges. The positive charges may be combined with negative charges by the negative voltage applied to the light shielding layer 160. Thus, the positive charges may be removed.

Referring again to FIG. 4, a second planarization layer 165, a color filter layer CF, and micro lenses ML may be formed on the light shielding layer 160. The second planarization layer 165 may be disposed between the light shielding layer 160 and the color filter layer CF, and may fill the holes HL. The second planarization layer 165 may include a transparent insulating material, for example, silicon oxide.

FIG. 11 is a graph illustrating a difference between dark levels of a pixel region and an optical black region versus a value of a negative voltage applied to a light shielding layer of an image sensor according to an exemplary embodiment of the inventive concept.

Referring to FIG. 11, the negative voltage applied to the light shielding layer 160 of the image sensor of FIG. 4 is changed from 0V to −2.8V at intervals of −0.4V. At this time, even though the negative voltage is changed, a value of a black level (dark level) of the pixel region PX is maintained at about 4.7 e⁻/s. On the contrary, as the negative voltage is changed from 0V to −2.8V, a value of a black level of the optical black region covered by the light shielding layer is reduced from about 5.4 e⁻/s to 4.7 e⁻/s. As a result, the remaining positive charges may be removed by the negative voltage applied to the light shielding layer, thereby reducing or minimizing a black level difference between the pixel region and the optical black region without an influence on the pixel region. As shown above, by applying a proper amount of the negative voltage to the light shielding layer, a black level of an optical black region covered by the light shielding layer may be reduced to a level close to or about the same as a black level of the pixel region.

According to an exemplary embodiment of the inventive concept, the light shielding layer may shield the light and may be connected to the charge pump applying the negative voltage. Thus, the light shielding layer may offset or remove the remaining positive charges. As a result, it is possible to reduce or minimize the black level difference between the optical black region and each of the pixel regions. Accordingly, the image sensor in an exemplary embodiment of the inventive concept having the remaining positive charges removed by a negative voltage may have a better photosensitivity.

While the inventive concept has been described with reference to example embodiments, it will be apparent to those skilled in the art that various changes and modifications may be made without departing from the spirits and scopes of the inventive concept. Therefore, it should be understood that the above embodiments are not limiting, but illustrative. Thus, the scopes of the inventive concept are to be determined by the broadest permissible interpretation of the following claims and their equivalents, and shall not be restricted or limited by the foregoing description.

What is claimed is:

1. An image sensor comprising:
a device isolation layer disposed in a substrate to define a plurality of pixel regions;
an interconnection structure disposed on a first surface of the substrate, the interconnection structure including an interconnection electrically connected to a transistor;
a light shielding layer disposed on a second surface, opposite to the first surface, of the substrate; and
a charge pump configured to apply a negative voltage to the light shielding layer,
wherein the light shielding layer has a grid structure having holes exposing the plurality of pixel regions, and
wherein the grid structure vertically overlaps with the device isolation layer.

2. The image sensor of claim 1, wherein the light shielding layer comprises:
a first portion surrounding the plurality of pixel regions; and
second portions intersecting an inner space of the first portion in a longitudinal direction and a transverse direction.

3. The image sensor of claim 1, wherein the light shielding layer includes at least one of tungsten (W), copper (Cu), hafnium (Hf), zirconium (Zr), titanium (Ti), tantalum (Ta), aluminum (Al), ruthenium (Ru), palladium (Pd), platinum (Pt), cobalt (Co), and nickel (Ni).

4. The image sensor of claim 1, further comprising:
a photoelectric conversion layer formed in each of the plurality of pixel regions to generate photocharges;
a well dopant layer disposed between the photoelectric conversion layer and the first surface of the substrate in each of the plurality of pixel regions, the well dopant layer doped with dopants of which a conductivity type is opposite to that of the photoelectric conversion layer; and
a transfer gate of the transistor transferring photocharges accumulated in the photoelectric conversion layer into a floating diffusion region.

5. The image sensor of claim 4, wherein the transfer gate comprises:
a lower portion inserted in the well dopant layer; and
an upper portion connected to the lower portion and protruding from the first surface of the substrate.

6. The image sensor of claim 4, wherein the transfer gate is disposed on the first surface of the substrate.

7. The image sensor of claim 4, wherein the floating diffusion region is disposed in the well dopant layer at a side of the transfer gate, and
wherein the floating diffusion region is doped with dopants of which a conductivity type is opposite to that of the well dopant layer.

8. The image sensor of claim 1, wherein positive charges remain between the second surface of the substrate and the light shielding layer, and
wherein the positive charges are removed by the negative voltage applied to the light shielding layer.

9. A method of manufacturing an image sensor, the method comprising:
forming a device isolation layer in a substrate to define pixel regions;
forming a photoelectric conversion layer and a floating diffusion region in each of the pixel regions;
forming an interconnection structure on a first surface of the substrate;
forming a light shielding layer on a second surface of the substrate;
performing a curing process on the second surface of the substrate; and
applying a negative voltage to the light shielding layer to remove positive charges remaining between the second surface of the substrate and the light shielding layer.

10. The method of claim 9, wherein the forming of the device isolation layer comprises:
etching through the first surface of the substrate to form a trench having a grid structure defining the pixel regions in the substrate; and
filling the trench with an insulating material.

11. The method of claim 9, wherein the forming of the light shielding layer comprises:
forming a metal layer completely covering the second surface of the substrate; and
patterning the metal layer to form holes exposing the pixel regions.

12. The method of claim 11, wherein the metal layer includes at least one of tungsten (W), copper (Cu), hafnium (Hf), zirconium (Zr), titanium (Ti), tantalum (Ta), aluminum (Al), ruthenium (Ru), palladium (Pd), platinum (Pt), cobalt (Co), and nickel (Ni).

13. The method of claim 9, further comprising:
electrically connecting the light shielding layer to a charge pump applying the negative voltage to the light shielding layer.

14. The method of claim 9, further comprising:
forming a color filter layer on the light shielding layer; and
forming micro lenses respectively corresponding to the pixel regions on the color filter layer.

15. The method of claim 9, further comprising:
forming a well dopant layer between the photoelectric conversion layer and the first surface of the substrate in each of the pixel regions before the formation of the floating diffusion region,
wherein the photoelectric conversion layer and the floating diffusion region are formed by ion implantation processes using dopants having a first conductivity type, and
wherein the well dopant layer is formed by an ion implantation process using dopants having a second conductivity type opposite to the first conductivity type.

16. An image sensor comprising:
a semiconductor substrate having a first surface and a second surface opposite to the first surface, and having a pixel region which includes a photoelectric conversion layer formed in the semiconductor substrate;
a well dopant layer disposed between the photoelectric conversion layer and the first surface of the semiconductor substrate in the pixel region;
a transfer gate disposed on the first surface of the semiconductor substrate for transferring photocharges accumulated in the photoelectric conversion layer into a floating diffusion region, the floating diffusion region disposed in the well dopant layer at a side of the transfer gate;
a light shielding layer disposed on the second surface of the semiconductor substrate, and having a hole exposing the pixel region; and
a charge pump connected to the light shielding layer configured to apply a negative voltage to remove positive charges.

17. The image sensor of claim 16, wherein the well dopant layer is doped with dopants of which a conductivity type is opposite to that of the photoelectric conversion layer, and the floating diffusion region is doped with dopants of which a conductivity type is opposite to that of the well dopant layer.

18. The image sensor of claim 16, further comprising:
an interconnection structure disposed on the first surface of the semiconductor substrate, and including an interconnection, a contact plug, and an interlayer insulating layer, wherein the interconnection is electrically connected to the floating diffusion region through the contact plug.

19. The image sensor of claim 16, wherein the light shielding layer includes at least one of tungsten (W), copper (Cu), hafnium (Hf), zirconium (Zr), titanium (Ti), tantalum (Ta), aluminum (Al), ruthenium (Ru), palladium (Pd), platinum (Pt), cobalt (Co), and nickel (Ni).

20. The image sensor of claim 16, wherein an amount of the negative voltage is applied to the light shielding layer to reduce a black level of an optical black region covered by the light shielding layer to a level about the same as a black level of the pixel region.
